(19) United States
(12) Patent Application Publication
(10) Pub. No.: US 2026/0068397 A1
(43) Pub. Date: Mar. 5, 2026

(54) DISPLAY MODULE AND MANUFACTUING METHOD THEREOF

(71) Applicant: AUO Corporation, Hsinchu City (TW)

(72) Inventors: TING-CHUN LAI, Hsinchu City (TW); Shiuan-Tzung CHENG, Hsinchu City (TW); Ching-Yao SHIH, Hsinchu City (TW); Cheng-Liang WANG, Hsinchu City (TW)

(21) Appl. No.: 18/971,594

(22) Filed: Dec. 6, 2024

(30) Foreign Application Priority Data
Sep. 4, 2024 (TW) 113133373

(51) Int. Cl. H10H 29/85; H10H 29/01; H10H 29/80; H10H 29/851

(52) U.S. Cl. CPC H10H 29/8517; H10H 29/034; H10H 29/0361; H10H 29/842; H10H 29/8514; H10H 29/942

(57) ABSTRACT

A display module includes: a substrate, a first dielectric layer, a second dielectric layer and a plurality of color filters. The substrate is disposed with a plurality of light-emitting diodes (LEDs) thereon. The LEDs have a non-smooth upper surface. The first dielectric layer is located on the substrate and surrounding the LEDs. The first dielectric layer is filled between the substrate and the second dielectric layer, and a refractive index of the second dielectric layer is greater than a refractive index of the first dielectric layer. The color filters are located on a side of the second dielectric layer opposite to the first dielectric layer.

### CROSS-REFERENCE TO RELATED PATENT APPLICATION

This non-provisional application claims priority to and the benefit of, pursuant to U.S.C. § 119(a), patent application No. 113133373 filed in Taiwan on Sep. 4, 2024. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to a display module, and in particular to a display module with relatively high emission rate and large viewing angle.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A display module emits light through light-emitting diodes (LEDs) and is correspondingly configured with, for example, primary color (red, green, blue) filters (also known as color filters) to form color pixels on the display panel. In the design of the display module, a layer of a sealed space, which may include air or other transparent encapsulating materials with a refractive index lower than that of glass, may exist between a top cover glass or the color filters and the LED array substrate, in order to reduce total internal reflection, thereby enhancing light output efficiency. However, a light-shielding material, such as a black matrix, may be placed between the color filters to prevent light reflection. When a user views the display module from a wider side viewing angle, the light emitted from the LEDs may be obstructed by the color filters or the black matrix, causing color shifts perceptible to the human eyes. Thus, there is a current industry expectation for a display module that improves light output efficiency and supports wide viewing angles.

### SUMMARY

One of the objectives of the present disclosure is to provide a display module, which is used to enhance the light output efficiency of light penetrating the display panel.

One of the objectives of the present disclosure is to provide a display module, which is used to reduce the color shift generated when a user views the display module from a wider side viewing angle.

In one embodiment, the display module includes a substrate, a plurality of light-emitting diodes (LEDs), a first dielectric layer, a second dielectric layer and a plurality of color filters. The LEDs are disposed on the substrate, and each of the LEDs have a non-smooth upper surface. The first dielectric layer is located on the substrate and surrounding the LEDs. The first dielectric layer is filled between the substrate and the second dielectric layer, and a refractive index of the second dielectric layer is greater than a refractive index of the first dielectric layer. The color filters are located on a side of the second dielectric layer opposite to the first dielectric layer.

In another embodiment, a method of manufacturing the display module includes: disposing a plurality of light-emitting diodes (LEDs) on a substrate, and forming a non-smooth upper surface on each of the LEDs; forming a first dielectric layer on the substrate, where the first dielectric layer surrounds the LEDs; forming a second dielectric layer, where the first dielectric layer is filled between the substrate and the second dielectric layer, and a refractive index of the second dielectric layer is greater than a refractive index of the first dielectric layer; and disposing a plurality of color filters on a side of the second dielectric layer opposite to the first dielectric layer.

With this configuration, the display module may reduce the obstruction of light emitted from the LEDs by internal components of the display module, thus lowering the light output efficiency, and may enhance light uniformity when the user views the display screen from a wider side viewing angle, thereby reducing the likelihood of color shifts occurring at large viewing angles.

These and other aspects of the present disclosure will become apparent from the following description of the embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a schematic view illustrating light emitted by the LEDs being obstructed by color filters or light shielding walls.

FIG. 2 is a schematic view illustrating a display module according to one embodiment of the present disclosure.

FIG. 3 is a schematic view illustrating increased light output efficiency of the display module according to one embodiment of the present disclosure compared to the conventional designs.

FIG. 4 is a schematic view illustrating a display module including a coating layer according to another embodiment of the present disclosure.

FIG. 5A is a schematic view illustrating a display module including a color conversion medium according to a further embodiment of the present disclosure.

FIG. 5B is a schematic view illustrating a display module including a color conversion medium according to a further embodiment of the present disclosure.

FIG. 6 is a flowchart illustrating a method of manufacturing a display module according to yet another embodiment of the present disclosure.

### DETAILED DESCRIPTION

Implementations of a display module disclosed in the present disclosure are described through specific embodiments and accompanying drawings as follows. Those skilled in the art can understand the advantages and effects of the present disclosure based on the content disclosed in the specification. However, the following disclosures are not intended to limit the scope of protection of the disclosure. Under principles that do not deviate from the spirit of the present disclosure, those skilled in the art may implement the disclosure in other different embodiments based on various perspectives and applications.

In the accompanying drawings, to clearly show the components, the thicknesses of the layers, films, panels and areas, etc. are enlarged. In the disclosure, identical drawing references indicates identical components. It should be understood that components such as the layers, films, panels and areas, etc., are referred to as being “on” or “connected to” another component, they may be on or connected to another component directly, or an intermediate component may exist therebetween. To the contrary, when a component is referred to as being “directly on” or “directly connected to” another component, there is no intermediate component therebetween. As used herein, being “connected” may refer to physical connection or electrical connection.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

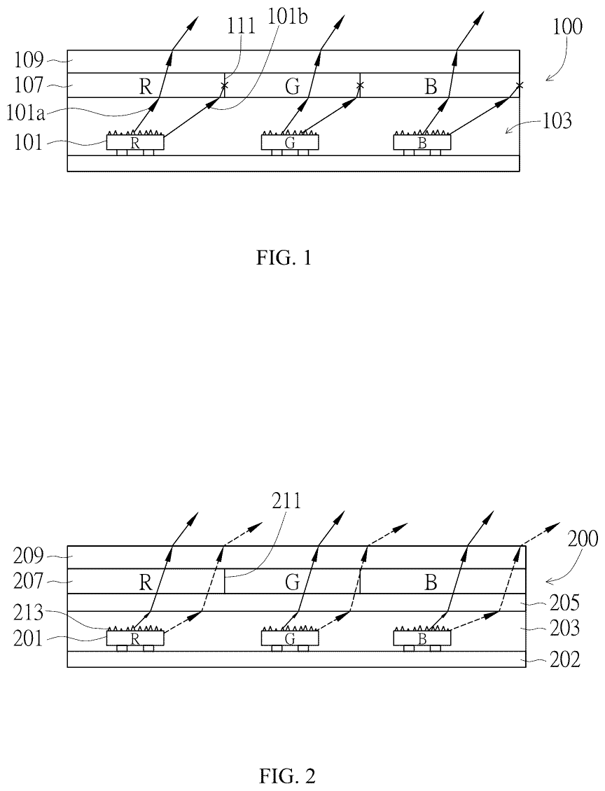

Referring to FIG. 1, which is a schematic view illustrating light emitted by the LEDs 101 in a display module 100 being obstructed. Since the refractive index of the color filters 107 is greater than that of the air 103, as shown in the figure, when the light 101a is emitted from the LEDs 101 and penetrates through the air 103 to enter the color filters 107, the light 101a will deviate toward the normal line, thus reducing the issue of total reflection when the light 101a leaves the glass 109. However, when the light 101b is emitted toward edges of the color filters 107, it is still possible that, even though the light 101b deviates toward the normal line, it may be obstructed by the adjacent color filter in a different color or the black matrix 111, thereby causing the user to perceive color shifts when viewing the display module 100 from a wider side viewing angle.

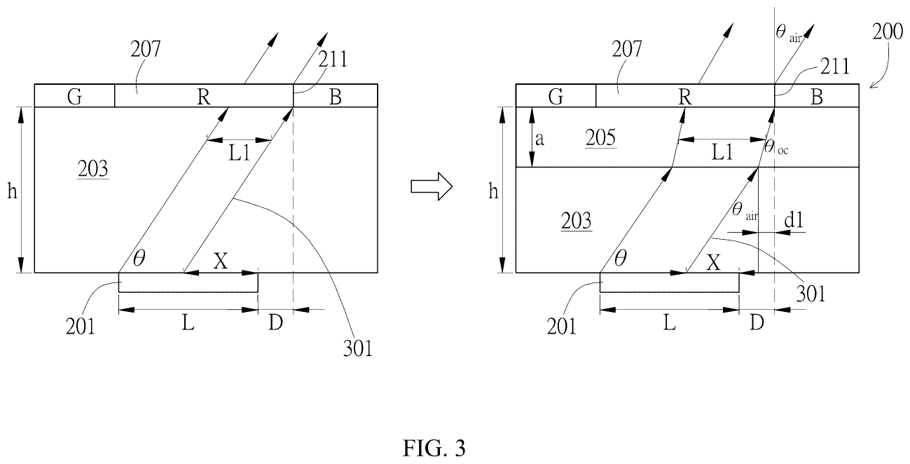

Referring to FIG. 2, which is a schematic view illustrating a display module 200 according to one embodiment of the present disclosure. In the present embodiment, the display module 200 includes a plurality of LEDs 201 disposed on the substrate 202, and each of the LEDs 201 have a rough or patterned upper surface 213, such that the light emitted from each LED 201 is scattered as it passes through the upper surface 213, thereby increasing the propagation path of the light. Further, the display module 200 further includes a first dielectric layer 203, a second dielectric layer 205, a color filter 207, and a transparent layer 209 sequentially on the substrate 202. The first dielectric layer 203 surrounds the LEDs 201 and is filled between the substrate 202 and the second dielectric layer 205, and a refractive index of the second dielectric layer 205 is greater than a refractive index of the first dielectric layer 203 (for example, the first dielectric layer 203 may be air, the second dielectric layer 205 a transparent encapsulation material with a refractive index greater than the air, and the transparent layer 209 is a material like glass). In addition, a light shielding wall 211, such as a black matrix, may be positioned between the color filters 207 without being limited thereto in order to prevent light reflection. It should be noted that, although the air is used as the first dielectric layer 203 and a transparent encapsulation material is used as the second dielectric layer in the present embodiment, it is possible that in other different embodiments, the first dielectric layer 203 and the second dielectric layer 205 may include other materials (for example, the first dielectric layer 203 may have a refractive index between 1 and 1.4, and the second dielectric layer 205 may have a refractive index between 1.5 and 2), and the present disclosure is not limited thereto.

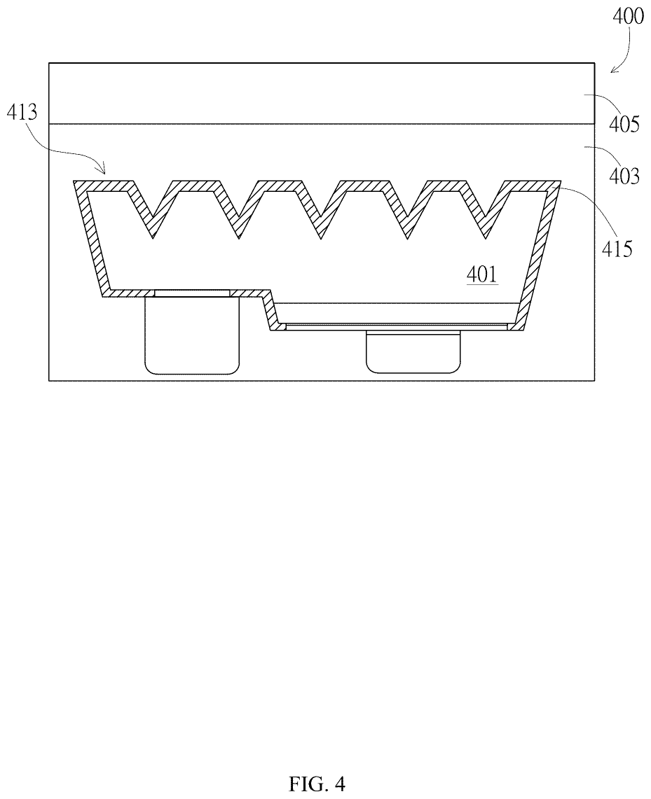

Referring to FIG. 3, which is a schematic view illustrating increased light output efficiency of the display module 200 according to one embodiment of the present disclosure. As shown in FIG. 3, the left side illustrates light emission of a display module with a conventional design, while the right side shows light emission of the display module 200 of the present disclosure. Assuming that the light 301 represents the light that may ultimately exit the display module 200 when being emitted from LED 201 toward the edge of a color filter 207 at the same emission angle. That is, for instance, when the LED 201 emits the light toward the right edge of the color filter 207, the light 301 represents the light that may successfully exit the display module 200 when emitted from the rightmost side of the light source at the same emission angle (i.e., any light source positioned further to the right of the light 301 on the LED 201 would be obstructed by the light shielding wall 211). Thus, the actual light-emitting length L₁ is calculated as the length L of the LED 201 minus the shielding length X, i.e., L₁=L−X. Firstly, in the conventional design, the formula for calculating the shielding length X is:

$$X = h * tan θ - D$$

where h represents a distance from the LED 201 to the color filter 207, θ represents an included angle between the light and the LED 201 (i.e., 90 degrees minus the emission angle), and D represents a distance from the edge of the LED 201 to the vertical projection point of the edge of the color filter 207 on the substrate 202. Next, the formula for calculating the shielding length X of the display module 200 of the present disclosure is:

$$X = ( h - a ) * tan {θ}_{air} - D + d 1$$

where a represents a thickness of the second dielectric layer 205, θₐᵢᵣ represents an incident angle of the light entering the second dielectric layer 205, and d1 represents a distance between vertical projection points of the incident point of the light 301 entering the second dielectric layer 205 and the incident point of the light 301 entering the color filter 207 on a same plane. The formula for calculating the d1 is:

$$d 1 = a * tan {θ}_{o c} , and$$

$${θ}_{o c} = {sin}^{- 1} ( {n}_{air} * sin {θ}_{air} ) / {n}_{o c}$$

where θ_{oc} represents an incident angle of the light 301 entering the color filter 207, nₐᵢᵣ represents the refractive index of the first dielectric layer 203, and n_{oc} represents the refractive index of the second dielectric layer 205. By substituting the above formula for d1 into the formula for calculating the shielding length X, the following formula is obtained:

$$X = ( h - a ) * tan {θ}_{air} - D - a * ( tan {θ}_{air} - tan {θ}_{oc} )$$

where the bolded part (i.e., a*(tan θₐᵢᵣ−tan θ_{oc})) represents the reduction in the shielding length X of the display module 200 in the present disclosure compared to the conventional design, which is the increase in the actual light emitting length L₁.

Through the comparison in FIG. 3, it can be observed that, on the premise of maintaining the distance from the LED 201 to the color filter 207 (i.e., h) constant, adding the second dielectric layer 205 may enhance the light emission efficiency of the LED 201, thus achieving the reduction of the color shift issues occurred when the user views the display module 200 at a larger side viewing angle.

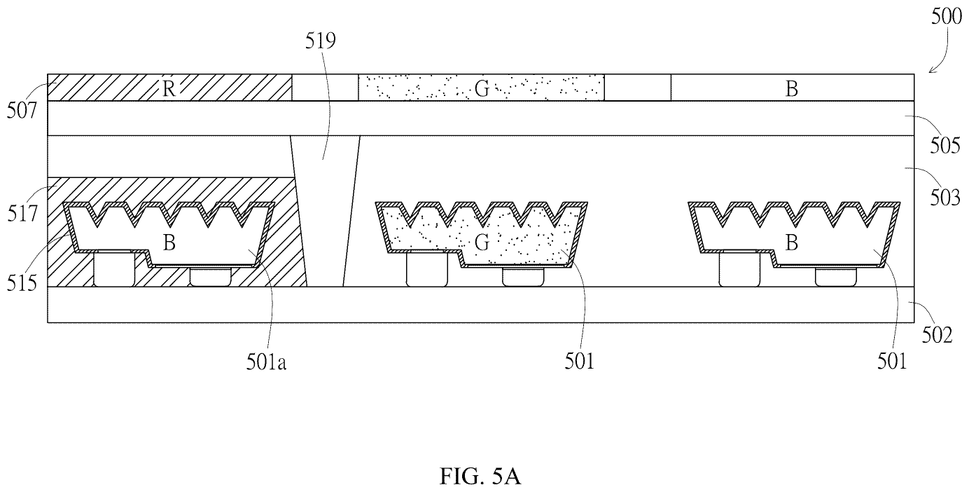

Referring to FIG. 4, which is a schematic view illustrating a display module 400 including a coating layer 415 according to another embodiment of the present disclosure. In the present embodiment, the coating layer 415 uniformly covers the upper surface 413 of the LED 401. Since the upper surface 413 is a non-smooth surface, the coating layer 415 also fluctuates along with the roughness of the upper surface 413 to achieve a complete coverage effect. A refractive index of the coating layer 415 is between the refractive index of the LED 401 and the refractive index of the first dielectric layer 403. For example, the coating layer 415 may be made of transparent materials such as silicon oxide or silicon nitride, or other suitable materials with a refractive index greater than that of the first dielectric layer 403 but less than that of the LED 401 (e.g., the refractive index of the coating layer 415 may range from 1.5 to 2.5, and the refractive index of the LED 401 may range from 2.2 to 3.5), and the present disclosure is not limited thereto. With this configuration, when the light is emitted from the LED 401 and before entering the second dielectric layer 405, it undergoes a process with the refractive index gradually decreasing, thereby increasing the light entering the second dielectric layer 405 and ultimately achieving the goal of enhancing the light output efficiency.

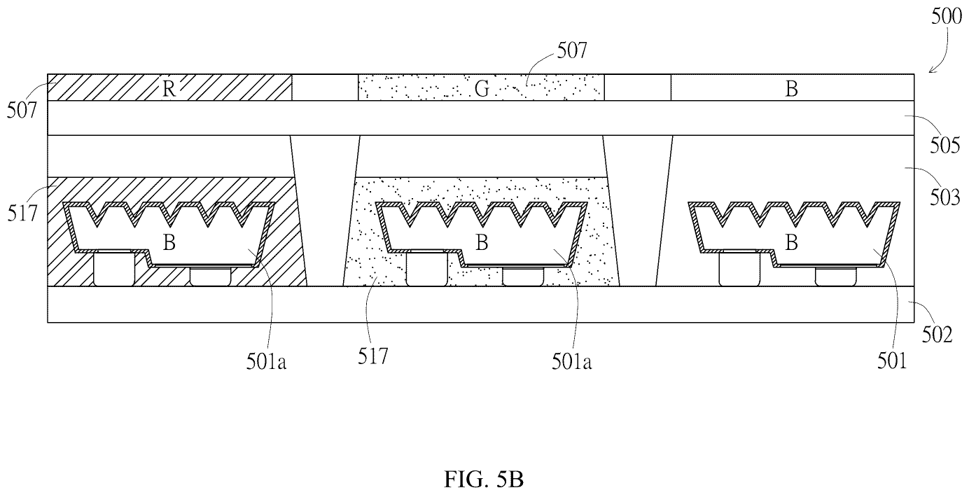

Referring to FIG. 5A, which is a schematic view illustrating a display module 500 including a color conversion medium 517 according to a further embodiment of the present disclosure. In the present embodiment, the color conversion medium 517 may replace a portion of the first dielectric layer 503 to surround the to-be-converted LED 501a. Further, the remaining first dielectric layer 503 is still located between the color conversion medium 517 and the second dielectric layer 505, and the display module 500 may further include the coating layer 515 as described in the above embodiment. That is, the light emitted from the LED 501 may sequentially pass through the coating layer 515, the color conversion medium 517, the first dielectric layer 503 and finally enter the second dielectric layer 505. In addition, the display module 500 further includes a partition wall 519. In the present embodiment, the partition wall 519 may connect the substrate 502 and the second dielectric layer 505, thus preventing the color conversion medium 517 from affecting the LEDs 501 other than the to-be-converted LED 501a. The color conversion medium 517 may include any suitable material, such as phosphor, that converts monochromatic light into light of other colors; and the present disclosure is not limited thereto. With this configuration, the light emitted from the LED 501 may be converted into light in different primary colors according to the pixel arrangement of the display module 500. For example, in the present embodiment, the to-be-converted LED 501a is a blue LED, and the color conversion medium 517 may convert the blue light emitted from the to-be-converted LED 501a into red light to match with the red color filter 507 corresponding to the to-be-converted LED 501a. It should be noted that, in other different embodiments, it is possible that the color conversion medium 517 is used to convert light emitted by the LEDs 501 of different colors, such as converting light emitted by green LEDs into the blue light or converting light emitted by red LEDs into the green light, and the present disclosure is not limited thereto. In addition, by providing the partition wall 519, the display module 500 may include multiple groups of color conversion media 517 simultaneously (as shown in FIG. 5B), and the present disclosure is not limited thereto.

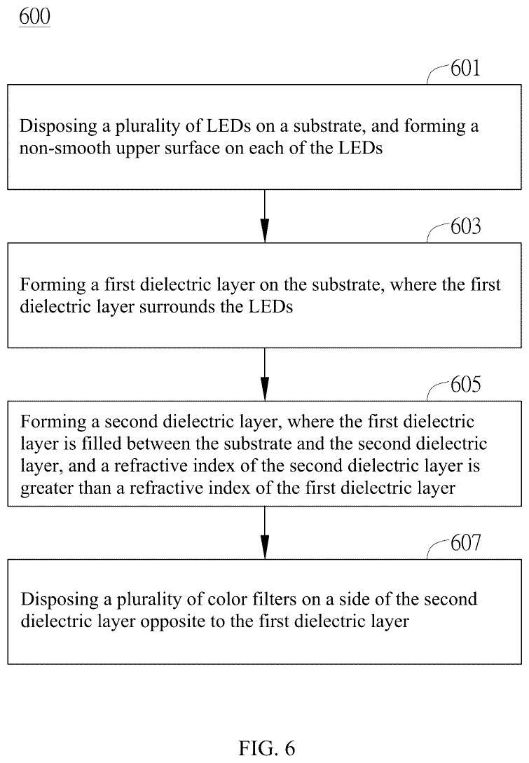

Referring to FIG. 6, which illustrates a method 600 of manufacturing a display module according to yet another embodiment of the present disclosure. In the present embodiment, the method 600 includes: disposing a plurality of LEDs on a substrate, and forming a non-smooth upper surface on each of the LEDs (601); forming a first dielectric layer on the substrate, where the first dielectric layer surrounds the LEDs (603); forming a second dielectric layer, where the first dielectric layer is filled between the substrate and the second dielectric layer, and a refractive index of the second dielectric layer is greater than a refractive index of the first dielectric layer (605); and disposing a plurality of color filters on a side of the second dielectric layer opposite to the first dielectric layer (607). In addition, the method 600 in the present embodiment may further include forming or disposing the components as described in the aforementioned embodiments (such as the light shielding wall as shown in FIG. 2; the coating layer as shown in FIG. 4; and the color conversion medium and the partition wall as shown in FIG. 5A), thus achieving the objectives of the present disclosure as described in the aforementioned embodiments.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A display module, comprising:
a substrate, disposed with a plurality of light-emitting diodes (LEDs) thereon, wherein each of the LEDs have a non-smooth upper surface;
a first dielectric layer, located on the substrate and surrounding the LEDs;
a second dielectric layer, wherein the first dielectric layer is filled between the substrate and the second dielectric layer, and a refractive index of the second dielectric layer is greater than a refractive index of the first dielectric layer; and
a plurality of color filters, located on a side of the second dielectric layer opposite to the first dielectric layer.

2. The display module according to claim 1, further comprising a plurality of light shielding walls, wherein the color filters are disposed to respectively correspond to the LEDs, and the light shielding walls are located between the color filters to separate the color filters.

3. The display module according to claim 2, further comprising a coating layer at least partially attached to the upper surface of the LEDs, wherein a refractive index of the coating layer is less than a refractive index of the LEDs and is greater than the refractive index of the first dielectric layer.

4. The display module according to claim 3, further comprising a transparent layer, located on a side of the color filters opposite to the second dielectric layer.

5. The display module according to claim 3, further comprising a color conversion medium and a partition wall, wherein the color conversion medium is located between the second dielectric layer and the substrate and encapsulates a to-be-converted LED of the LEDs, and wherein the partition wall is configured to prevent the color conversion medium from being in contact with the LEDs other than the to-be-converted LED.

6. The display module according to claim 2, further comprising a transparent layer, located on a side of the color filters opposite to the second dielectric layer.

7. The display module according to claim 2, further comprising a color conversion medium and a partition wall, wherein the color conversion medium is located between the second dielectric layer and the substrate and encapsulates a to-be-converted LED of the LEDs, and wherein the partition wall is configured to prevent the color conversion medium from being in contact with the LEDs other than the to-be-converted LED.

8. A method of manufacturing a display module, comprising:
disposing a plurality of light-emitting diodes (LEDs) on a substrate, and forming a non-smooth upper surface on each of the LEDs;
forming a first dielectric layer on the substrate, wherein the first dielectric layer surrounds the LEDs;
forming a second dielectric layer, wherein the first dielectric layer is filled between the substrate and the second dielectric layer, and a refractive index of the second dielectric layer is greater than a refractive index of the first dielectric layer; and
disposing a plurality of color filters on a side of the second dielectric layer opposite to the first dielectric layer.

9. The method according to claim 8, wherein the disposing the color filters comprises:
disposing the color filters to respectively correspond to the LEDs, and
disposing a plurality of light shielding walls between the color filters to separate the color filters.

10. The method according to claim 9, further comprising:
forming a coating layer at least partially attached to the upper surface of the LEDs, wherein a refractive index of the coating layer is less than a refractive index of the LEDs and is greater than the refractive index of the first dielectric layer.

11. The method according to claim 10, further comprising:
forming a transparent layer, wherein the transparent is located on a side of the color filters opposite to the second dielectric layer.

12. The method according to claim 10, further comprising:
forming a color conversion medium and a partition wall, wherein the color conversion medium is located between the second dielectric layer and the substrate and encapsulates a to-be-converted LED of the LEDs, and wherein the partition wall is configured to prevent the color conversion medium from being in contact with the LEDs other than the to-be-converted LED.

11. The method according to claim 9, further comprising:
forming a transparent layer, wherein the transparent is located on a side of the color filters opposite to the second dielectric layer.

12. The method according to claim 9, further comprising:
forming a color conversion medium and a partition wall, wherein the color conversion medium is located between the second dielectric layer and the substrate and encapsulates a to-be-converted LED of the LEDs, and wherein the partition wall is configured to prevent the color conversion medium from being in contact with the LEDs other than the to-be-converted LED.
